(19) United States
(12) Patent Application Publication
(10) Pub. No.: US 2015/0333018 A1
(43) Pub. Date: Nov. 19, 2015

(54) SEMICONDUCTOR PACKAGE AND METHOD OF MANUFACTURING THE SAME

(71) Applicants: Dong-Kwan KIM, Hwaseong-si (KR); Hee-Jeong KIM, Seoul (KR); Nam-Kyu BAEK, Hwaseong-si (KR)

(72) Inventors: Dong-Kwan KIM, Hwaseong-si (KR); Hee-Jeong KIM, Seoul (KR); Nam-Kyu BAEK, Hwaseong-si (KR)

(21) Appl. No.: 14/586,941

(22) Filed: Dec. 30, 2014

(30) Foreign Application Priority Data
May 14, 2014 (KR) 10-2014-0057501

(51) Int. Cl. H01L 23/552; H01L 43/12; H01L 43/02

(52) U.S. Cl. CPC H01L 23/552; H01L 43/02; H01L 43/12

(57) ABSTRACT

A semiconductor package may include a package substrate, an MRAM chip, a first magnetic shielding film and a second magnetic shielding film. The MRAM chip may be arranged over the package substrate. The MRAM chip may be electrically connected with the package substrate. The first magnetic shielding film may attach the MRAM chip to the package substrate. The first magnetic shielding film may shield magnetic interference between the MRAM chip and the package substrate. The second magnetic shielding film may be arranged over the MRAM chip to shield magnetic interference at an upper region over the MRAM chip. Thus, the magnetic shielding layer may be arranged between the bonding pads of the MRAM chip so that magnetic interference between the bonding pads may be suppressed.

### CROSS-RELATED APPLICATION

This application claims priority under 35 USC §119 to Korean Patent Application No. 10-2014-0057501, filed on May 14, 2014 in the Korean Intellectual Property Office (KIPO), the contents of which are herein incorporated by reference in their entirety.

### BACKGROUND

1. Field

Example embodiments relate to a semiconductor package and a method of manufacturing the same. More particularly, example embodiments relate to a semiconductor package including a magnetic random access memory (MRAM) chip, and a method of manufacturing the semiconductor package.

2. Description of the Related Art

A magnetic field switching technique is utilized in operating an MRAM chip. A magnetic field applied to the MRAM chip may, however, cause malfunctions in the MRAM chip.

### SUMMARY

Example embodiments provide a semiconductor package that may be capable of suppressing magnetic interference between bonding pads.

Example embodiments also provide a method of manufacturing the above-mentioned semiconductor package by simple processes.

According to some example embodiments, there may be provided a semiconductor package. The semiconductor package may include a package substrate, an MRAM chip, a first magnetic shielding film and a second magnetic shielding film. The MRAM chip may be arranged over the package substrate. The MRAM chip may be electrically connected with the package substrate. The first magnetic shielding film may attach the MRAM chip to the package substrate. The first magnetic shielding film may suppress or reduce magnetic interference between the MRAM chip and the package substrate. The second magnetic shielding film may be arranged over the MRAM chip to suppress or reduce magnetic interference at an upper region over the MRAM chip.

In example embodiments, the first magnetic shielding film and the second magnetic shield film may include a first adhesive layer and a magnetic shielding layer stacked on the first adhesive layer.

In example embodiments, the first magnetic shielding film and the second magnetic shielding film may further include a second adhesive layer stacked on the magnetic shielding layer.

In example embodiments, the MRAM chip may include bonding pads arranged on an upper surface of the MRAM chip. The semiconductor package may further include conductive wires electrically connected between the bonding pads and the package substrate.

In example embodiments, the bonding pads may be covered by the second magnetic shielding film.

In example embodiments, the MRAM chip may include bonding pads arranged on a lower surface of the MRAM chip. The semiconductor package may further include conductive bumps electrically connected between the bonding pads and the package substrate.

In example embodiments, the first magnetic shielding film may have openings configured to expose the bonding pads.

In example embodiments, the semiconductor package may further include a second MRAM chip and a third MRAM chip. The second MRAM chip may be arranged over the second magnetic shielding film. The second MRAM chip may be electrically connected with the package substrate. The third MRAM chip may be arranged over the second MRAM chip. The third MRAM chip may be configured to cover bonding pads of the second MRAM chip.

In example embodiments, the semiconductor package may further include a molding member formed on an upper surface of the package substrate to cover the MRAM chip and the second magnetic shielding film.

In example embodiments, the semiconductor package may further include external terminals mounted on a lower surface of the package substrate.

According to some embodiments, there may be provided a method of manufacturing a semiconductor package. In the method of manufacturing the semiconductor package, a first magnetic shielding film may be attached to a first surface of a semiconductor substrate including a plurality of MRAM chips. The semiconductor substrate may be attached to a package substrate using the first magnetic shielding film. The MRAM chips may be electrically connected with the package substrate. A second magnetic shielding film may be attached to a second surface of the semiconductor substrate opposite to the first surface.

In example embodiments, electrically connecting the MRAM chips with the package substrate may include connecting bonding pads of the MRAM chips with the package substrate using conductive wires.

In example embodiments, electrically connecting the MRAM chips with the package substrate may include connecting bonding pads of the MRAM chips with the package substrate using conductive bumps.

In example embodiments, electrically connecting the MRAM chips with the package substrate may further include forming openings configured to expose the bonding pads of the MRAM chips.

In example embodiments, the method may further include attaching a second MRAM chip to an upper surface of the second magnetic shielding film, and attaching a third magnetic shielding film to an upper surface of the second MRAM chip.

In example embodiments, the method may further include forming a molding member on an upper surface of the package substrate to cover the MRAM chips and the second magnetic shielding film.

In example embodiments, the method may further include mounting external terminals on a lower surface of the package substrate.

According to example embodiments, the MRAM chip may be shielded by the magnetic shielding film having a die attaching function. Thus, the magnetic shielding layer may be arranged between the bonding pads of the MRAM chip. As a result, the magnetic interference between the bonding pads may be suppressed. Further, the magnetic shielding film may be attached to the semiconductor substrate including the MRAM chips. Therefore, the semiconductor packaging process may be simplified.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 is a cross-sectional view illustrating a semiconductor package in accordance with example embodiments;

FIG. 2 is a plan view illustrating a first MRAM chip of the semiconductor package in FIG. 1;

FIG. 3 is a plan view illustrating a second MRAM chip of the semiconductor package in FIG. 1;

FIGS. 4 to 9 are cross-sectional views illustrating a method of manufacturing the semiconductor package in FIG. 1;

FIG. 10 is a cross-sectional view illustrating a semiconductor package in accordance with example embodiments;

FIG. 11 is a cross-sectional view illustrating a semiconductor package in accordance with example embodiments;

FIGS. 12 to 16 are cross-sectional views illustrating a method of manufacturing the semiconductor package in FIG. 11; and

FIG. 17 is a cross-sectional view illustrating a semiconductor package in accordance with example embodiments.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

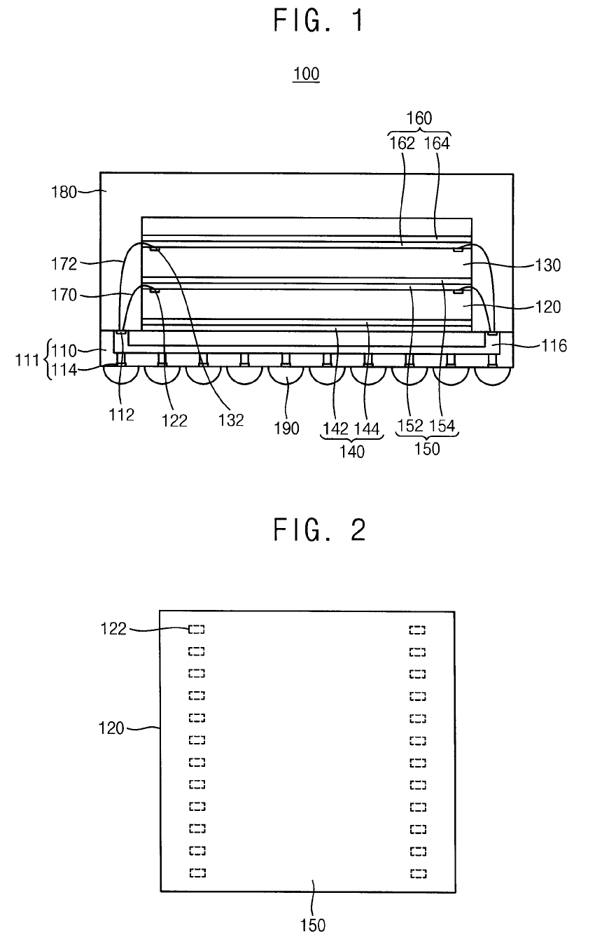

FIG. 1 is a cross-sectional view illustrating a semiconductor package in accordance with example embodiments; FIG. 2 is a plan view illustrating a first MRAM chip of the semiconductor package in FIG. 1; and FIG. 2 is a plan view illustrating a second MRAM chip of the semiconductor package in FIG. 1.

Referring to FIG. 1, a semiconductor package 100 of this example embodiment may include a package substrate 110, a first MRAM chip 120, a second MRAM chip 130, a first magnetic shielding film 140, a second magnetic shielding film 150, a third magnetic shielding film 160, a first conductive wire 170, a second conductive wire 172, a molding member 180 and external terminals 190.

The package substrate 111 may include an insulating substrate 110, upper pads 112, lower pads 114 and connecting lines 116. The upper pads 112 may be arranged on an upper surface of the insulating substrate 110. The lower pads 114 may be arranged on a lower surface of the insulating substrate 110. The connecting lines 116 may be formed in the insulating substrate 110 to electrically connect the upper pads 112 with the lower pads 114.

The first MRAM chip 120 may be positioned over the package substrate 110. The first MRAM chip 120 may include first bonding pads 122. The first bonding pads 122 may be arranged on both edge portions of an upper surface of the first MRAM chip 120.

The first magnetic shielding film 140 may be interposed between the first MRAM chip 120 and the package substrate 110. The first magnetic shielding film 140 may include a first adhesive layer 142 and a first magnetic shielding layer 144 stacked on the first adhesive layer 142. The first adhesive layer 142 may be used to attach the first MRAM chip 120 to the package substrate 110. The first magnetic shielding layer 144 may suppress or reduce magnetic interference between the first MRAM chip 120 and the package substrate 110, shielding the first MRAM chip 120 from magnetic interference. The first magnetic shielding layer 144 may include a metal such as aluminum, copper, nickel, etc.

The second MRAM chip 130 may be positioned over the first MRAM chip 120. The second MRAM chip 130 may include second bonding pads 132. The second bonding pads 132 may be arranged on both edge portions of an upper surface of the second MRAM chip 130.

The second magnetic shielding film 150 may be interposed between the first MRAM chip 120 and the second MRAM chip 130. The second magnetic shielding film 150 may include a second adhesive layer 152 and a second magnetic shielding layer 154 stacked on the second adhesive layer 152. The second adhesive layer 152 may be used to attach the first MRAM chip 120 to the second MRAM chip 130. The second magnetic shielding layer 154 may suppress or reduce magnetic interference between the first MRAM chip 120 and the second MRAM chip 130, shielding the first MRAM chip 120 and the second MRAM chip 130 from magnetic interference. The second magnetic shielding layer 154 may include a metal such as aluminum, copper, nickel, etc.

Referring to FIG. 2, the second magnetic shielding film 150 may be configured to cover substantially the entire upper surface of the first MRAM chip 120. Further, the second magnetic shielding film 150 may be configured to cover the first bonding pads 122. Thus, the second magnetic shielding film 150 may be positioned between the first bonding pads 122 so that magnetic interference between the first bonding pads 122 may be suppressed.

The third magnetic shielding film 160 may be arranged on an upper surface of the second MRAM chip 130. The third magnetic shielding film 160 may include a third adhesive layer 162 and a third magnetic shielding layer 164 stacked on the third adhesive layer 162. The third adhesive layer 162 may be used to attach the third magnetic shielding layer 164 to the second MRAM chip 130. The third magnetic shielding layer 164 may suppress or reduce magnetic interference between the second MRAM chip 130 and a structure over the second MRAM chip 130. The third magnetic shielding layer 164 may include a metal such as aluminum, copper, nickel, etc.

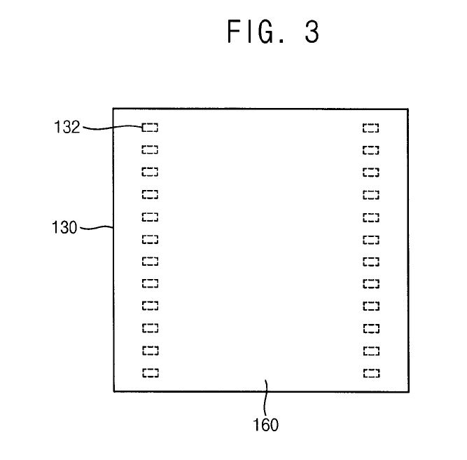

Referring to FIG. 3, the third magnetic shielding film 160 may be configured to cover substantially the entire upper surface of the second MRAM chip 130. Further, the third magnetic shielding film 160 may be configured to cover the second bonding pads 132. Thus, the third magnetic shielding film 160 may be positioned between the second bonding pads 132 so that the magnetic interference between the second bonding pads 132 may be suppressed.

The first conductive wire 170 may be electrically connected between the first bonding pads 122 of the first MRAM chip 120 and the upper pads 112 of the package substrate 110. The second conductive wire 172 may be electrically connected between the second bonding pads 132 of the second MRAM chip 120 and the upper pads 112 of the package substrate 110.

The molding member or molding layer 180 may be formed on the upper surface of the package substrate 110 to cover the third magnetic shielding film 160. The molding member 180 may protect the first MRAM chip 120, the second MRAM chip 130, the first magnetic shielding film 140, the second magnetic shielding film 150, the third magnetic shielding film 160, the first conductive wire 170 and the second conductive wire 172 from the external environment. The molding member 180 may include epoxy molding compound (EMC).

The external terminals 190 may be attached to the lower pads 114 of the package substrate 110. The external terminals 190 may be solder balls.

In example embodiments, the semiconductor package 100 may include the two MRAM chips 120 and 130. Alternatively, the semiconductor package 100 may include one MRAM chip or three or more MRAM chips stacked therein.

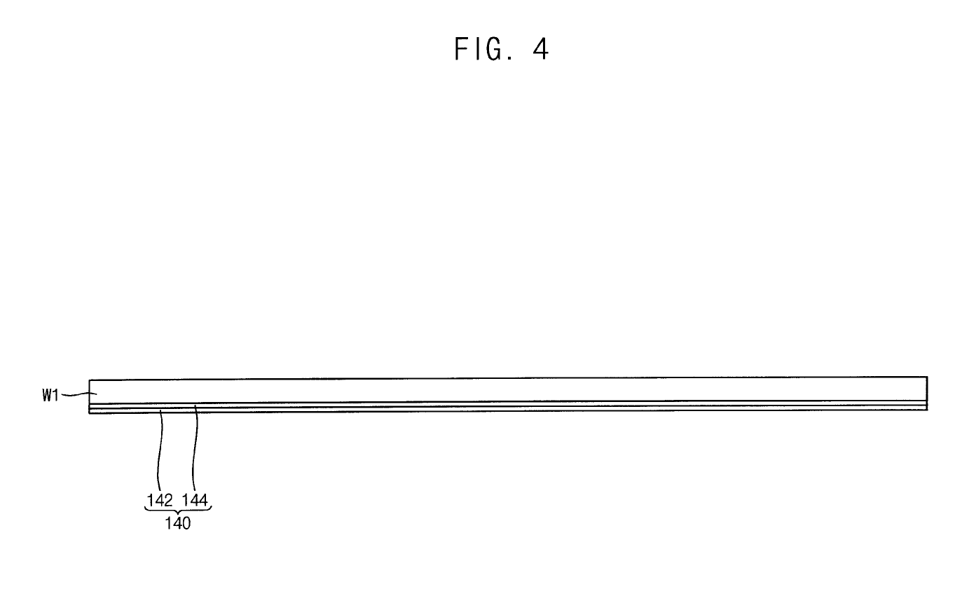

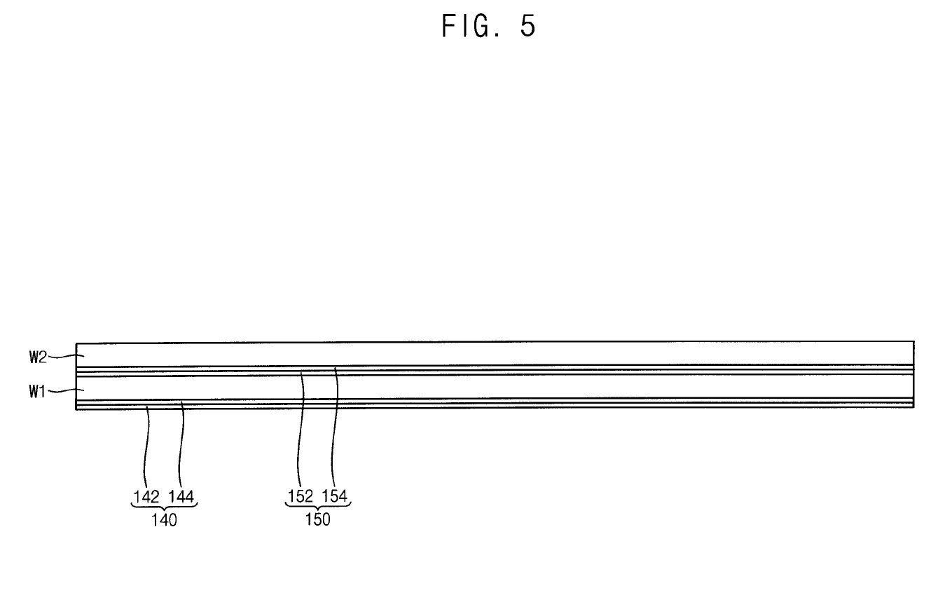

FIGS. 4 to 9 are cross-sectional views illustrating a method of manufacturing the semiconductor package in FIG. 1.

Referring to FIG. 4, the first magnetic shielding film 140 may be attached to a lower surface of a first semiconductor substrate W1. The first semiconductor substrate W1 may include a plurality of the first MRAM chips 120.

Referring to FIG. 5, the second magnetic shielding film 150 may be attached to an upper surface of the first semiconductor substrate W1. A second semiconductor substrate W2 may be arranged on an upper surface of the second magnetic shielding film 150. The second semiconductor substrate W2 may include a plurality of the second MRAM chips 130.

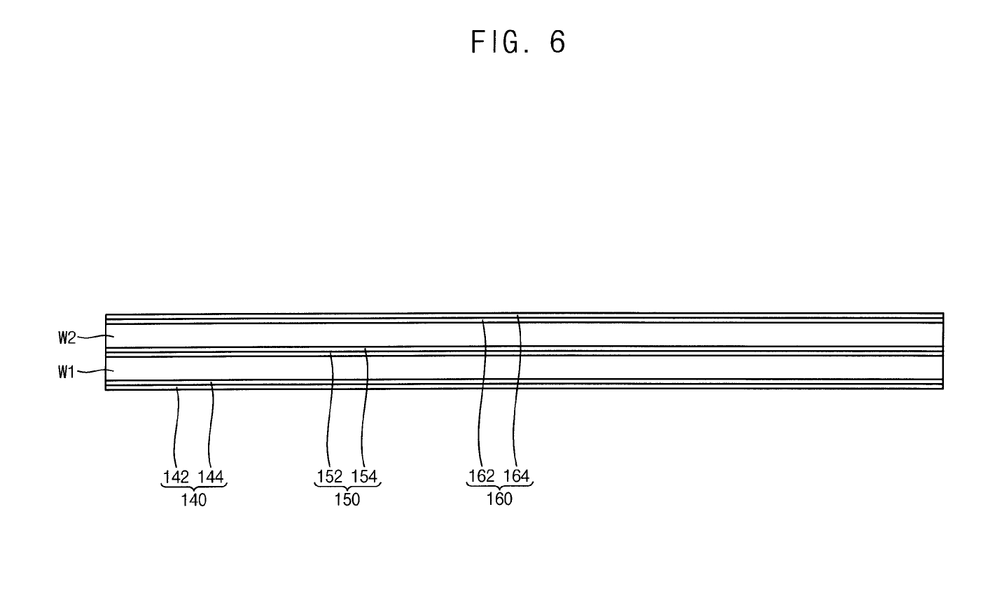

Referring to FIG. 6, the third magnetic shielding film 160 may be attached to an upper surface of the second semiconductor substrate W2.

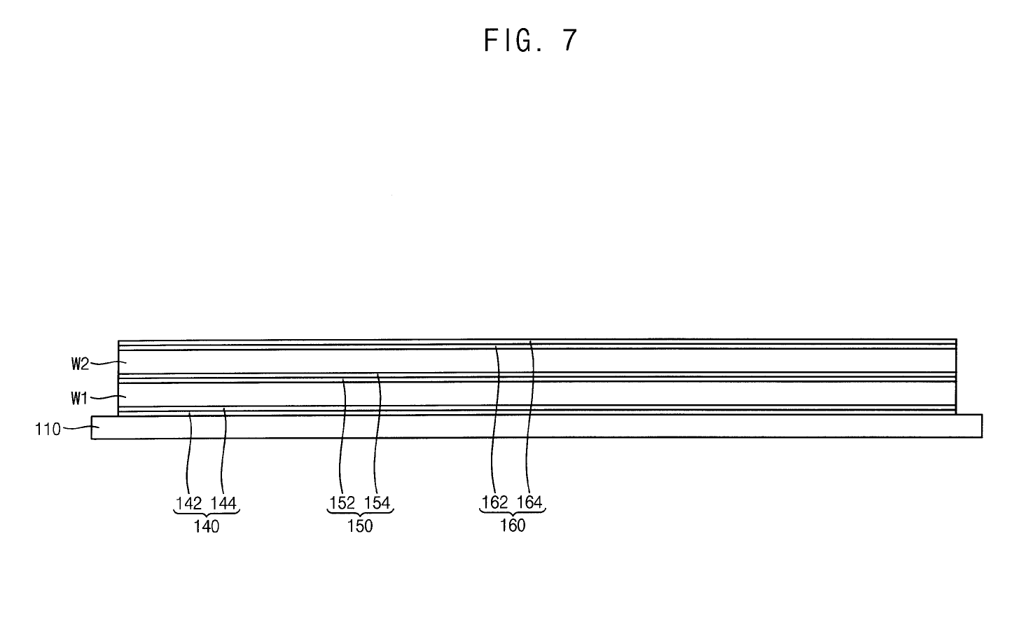

Referring to FIG. 7, the stacked first and second semiconductor substrates W1 and W2 may be attached to the upper surface of the package substrate 110.

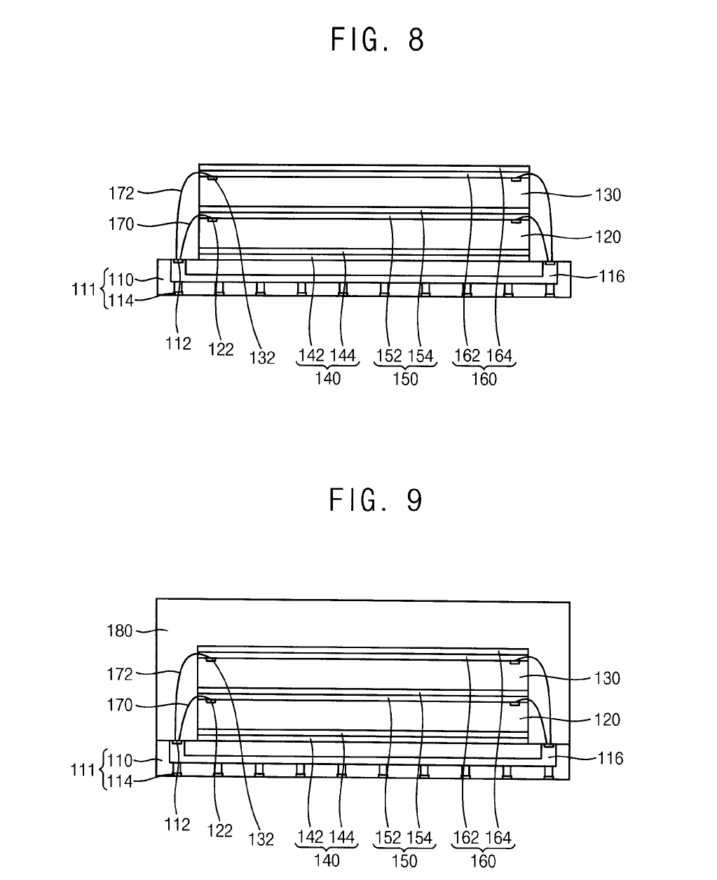

Referring to FIG. 8, the first semiconductor substrate W1, the second semiconductor substrate W2 and the package substrate 110 may be cut along scribe lanes of the first and second semiconductor substrates W1 and W2 to singulate the stacked first and second MRAM chips 120 and 130.

The first conductive wire 170 may be electrically connected between the first bonding pads 122 of the first MRAM chip 120 and the upper pads 112 of the package substrate 110. The second conductive wire 172 may be electrically connected between the second bonding pads 132 of the second MRAM chip 130 and the upper pads 112 of the package substrate 110.

Referring to FIG. 9, the molding member 180 may be formed on the upper surface of the package substrate 110.

The external terminals 190 may be mounted on the lower pads 114 of the package substrate 110 to complete the semiconductor package 100.

According to this example embodiment, the second magnetic shielding film 150 may be positioned between the first bonding pads 122 and the third magnetic shielding film 160 may be positioned between the second bonding pads 132. Thus, the magnetic interference between the first bonding pads and the magnetic interference between the second bonding pads may be suppressed. Further, the packaging processes may be performed under that the first to third magnetic shielding films may be attached to the semiconductor substrates including the MRAM chips so that the semiconductor packaging process may be simplified.

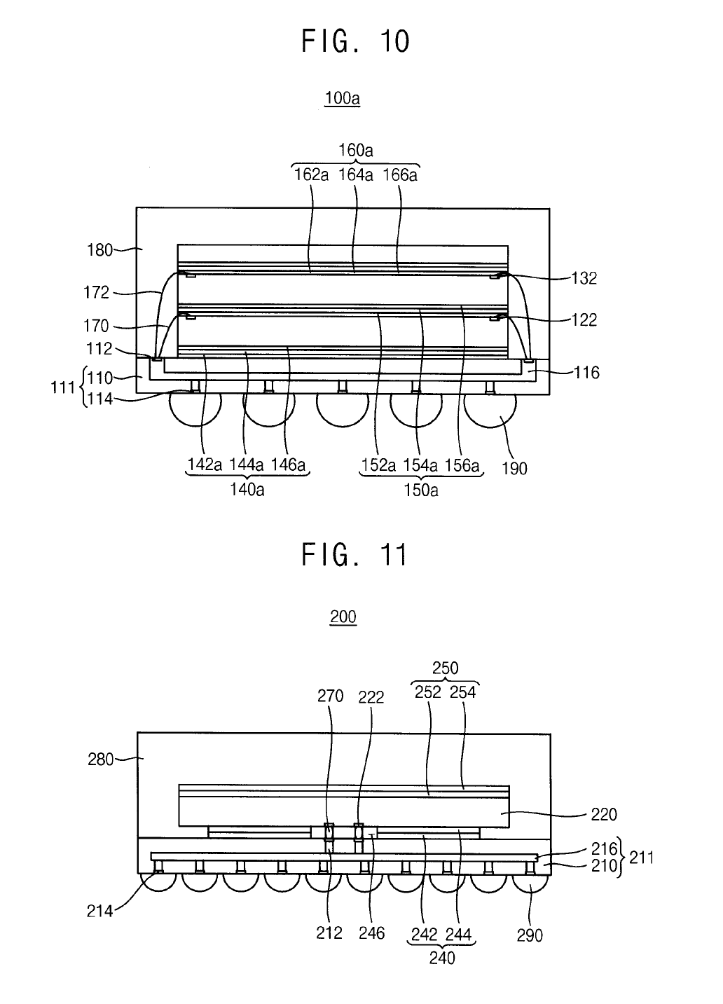

FIG. 10 is a cross-sectional view illustrating a semiconductor package in accordance with example embodiments.

A semiconductor package 100a of this example embodiment may include elements substantially the same as those of the semiconductor package 100 in FIG. 1 except for first to third magnetic shielding films. Thus, the same reference numerals may refer to the same elements and any further illustrations with respect to the same elements may be omitted herein for brevity.

Referring to FIG. 10, each of first to third magnetic shielding films 140a, 150a and 160a of the semiconductor package 100a may have a triple-layer structure.

The first magnetic shielding film 140a may include a first lower adhesive layer 142a, a first upper adhesive layer 146a and a first magnetic shielding layer 144a interposed between the first lower adhesive layer 142a and the first upper adhesive layer 146a. The first upper adhesive layer 146a may insulate the first magnetic shielding layer 144a from the first MRAM chip 120.

The second magnetic shielding film 150a may include a second lower adhesive layer 152a, a second upper adhesive layer 156a and a second magnetic shielding layer 154a interposed between the second lower adhesive layer 152a and the second upper adhesive layer 156a. The second upper adhesive layer 156a may insulate the second magnetic shielding layer 154a from the second MRAM chip 130.

The third magnetic shielding film 160a may include a third lower adhesive layer 162a, a third upper adhesive layer 166a and a third magnetic shielding layer 164a interposed between the third lower adhesive layer 162a and the third upper adhesive layer 166a. Alternatively, because the molding member or molding layer 180 may cover the third magnetic shielding layer 164a, it may not required to arrange the third upper adhesive layer 166a on an upper surface of the third magnetic shielding layer 164a. In this case, the third magnetic shielding film 160a may include the third lower adhesive layer 162a and the third magnetic shielding layer 164a.

A method of manufacturing the semiconductor package 100a in FIG. 10 may include process substantially the same as those illustrated with reference to FIGS. 4 to 9 except for the first to third magnetic shielding films 140a, 150a and 160a having the triple-layer structure. Thus, any further illustrations with respect to the method of manufacturing the semiconductor package 100a may be omitted herein for the sake of brevity.

The second upper adhesive layer 156a may insulate the second magnetic shielding layer 154a from the second MRAM chip 130.

FIG. 11 is a cross-sectional view illustrating a semiconductor package in accordance with example embodiments.

Referring to FIG. 11, a semiconductor package 200 of this example embodiment may include a package substrate 211, an MRAM chip 220, a first magnetic shielding film 240, a second magnetic shielding film 250, a conductive bump 270, a molding member or molding layer 280 and external terminals 290.

The package substrate 211 may include an insulating substrate 210, upper pads 212, lower pads 214 and connecting lines 216. The upper pads 212 may be arranged on an upper surface of the insulating substrate 210. The lower pads 214 may be arranged on a lower surface of the insulating substrate 210. The connecting lines 216 may be formed in the insulating substrate 210 to electrically connect the upper pads 212 with the lower pads 214.

The MRAM chip 220 may be positioned over the package substrate 210. The MRAM chip 220 may include bonding pads 222. The bonding pads 222 may be arranged on a substantially central portion of a lower surface of the MRAM chip 220.

The first magnetic shielding film 240 may be interposed between the MRAM chip 220 and the package substrate 210. The first magnetic shielding film 240 may have openings to expose the bonding pads 222. The first magnetic shielding film 240 may include a first adhesive layer 242 and a first magnetic shielding layer 244 stacked on the first adhesive layer 242. The first adhesive layer 242 may attach the MRAM chip 220 to the package substrate 210. The first magnetic shielding layer 244 may shield magnetic interference between the MRAM chip 220 and the package substrate 210. The first magnetic shielding layer 244 may include a metal such as aluminum, copper, nickel, etc.

The second magnetic shielding film 250 may be arranged on an upper surface of the MRAM chip 220. The second magnetic shielding film 250 may include a second adhesive layer 252 and a second magnetic shielding layer 254 stacked on the second adhesive layer 252. The second adhesive layer 252 may attach the second magnetic shielding layer 254 to the MRAM chip 220. The second magnetic shielding layer 254 may shield magnetic interference between the MRAM chip 220 and a structure over the MRAM chip 220. The second magnetic shielding layer 254 may include a metal such as aluminum, copper, nickel, etc.

The conductive bump 270 may be arranged in the openings of the first magnetic shielding film 240. The conductive bump 270 may be electrically connected between the bonding pads 222 of the MRAM chip 220 and the upper pads 112 of the package substrate 110.

The molding member or molding layer 280 may be formed on the upper surface of the package substrate 210 to cover the second magnetic shielding film 250. The external terminals 290 may be mounted on the lower pads 214 of the package substrate 210.

In example embodiments, the first and second magnetic shielding films 240 and 250 may have a double-layer structure. Alternatively, the first and second magnetic shielding films 240 and 250 may have a triple-layer structure in FIG. 10.

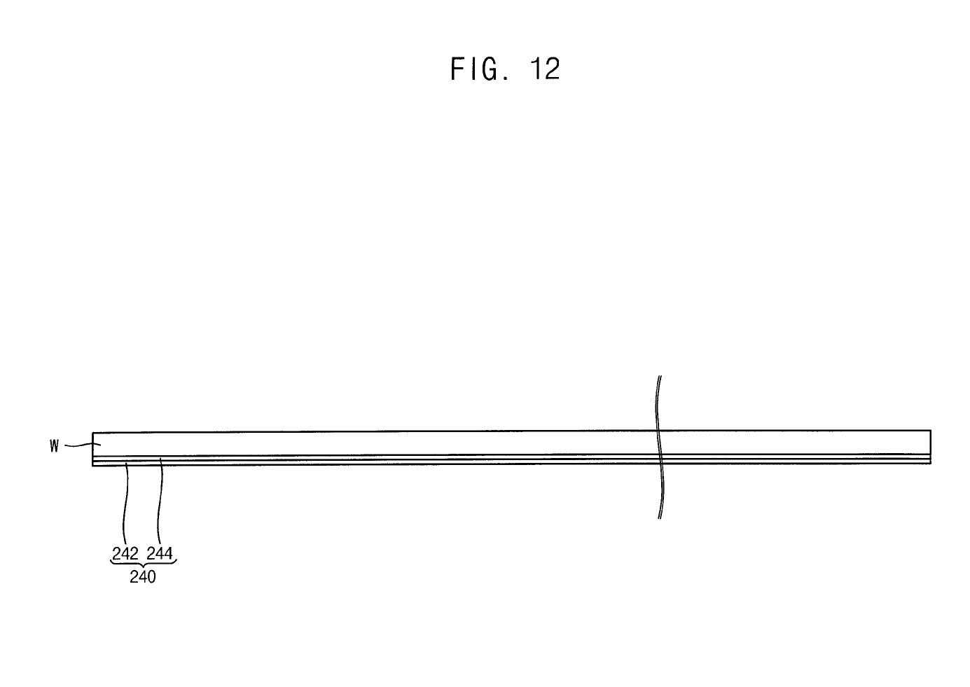

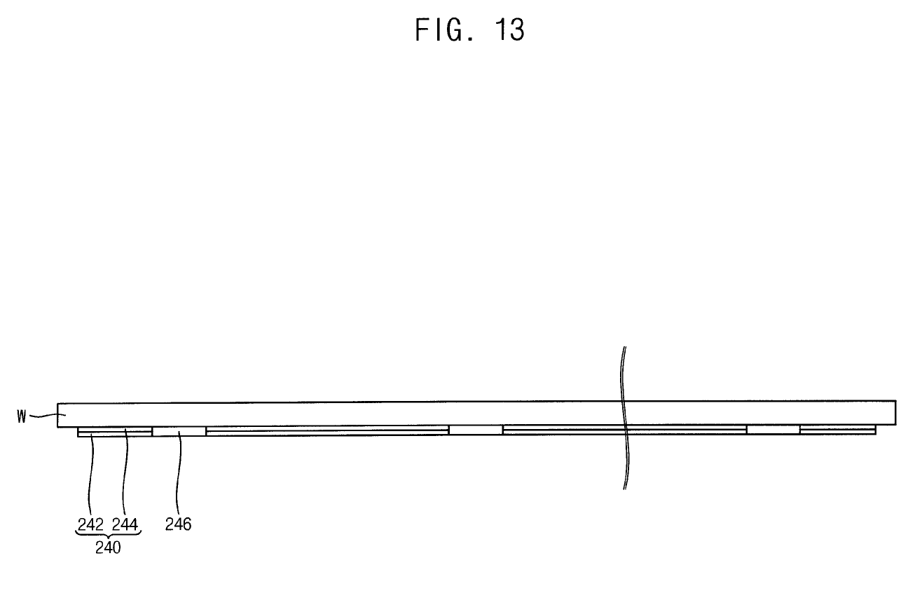

FIGS. 12 to 16 are cross-sectional views illustrating a method of manufacturing the semiconductor package in FIG. 11.

Referring to FIG. 12, the first magnetic shielding film 240 may be attached to a lower surface of a semiconductor substrate W. The semiconductor substrate W may include a plurality of the MRAM chips 220.

Referring to FIG. 13, the first magnetic shielding film 240 may be patterned to form the openings 246 therein. The bonding pads 222 of the MRAM chip 220 may be exposed through the openings 246.

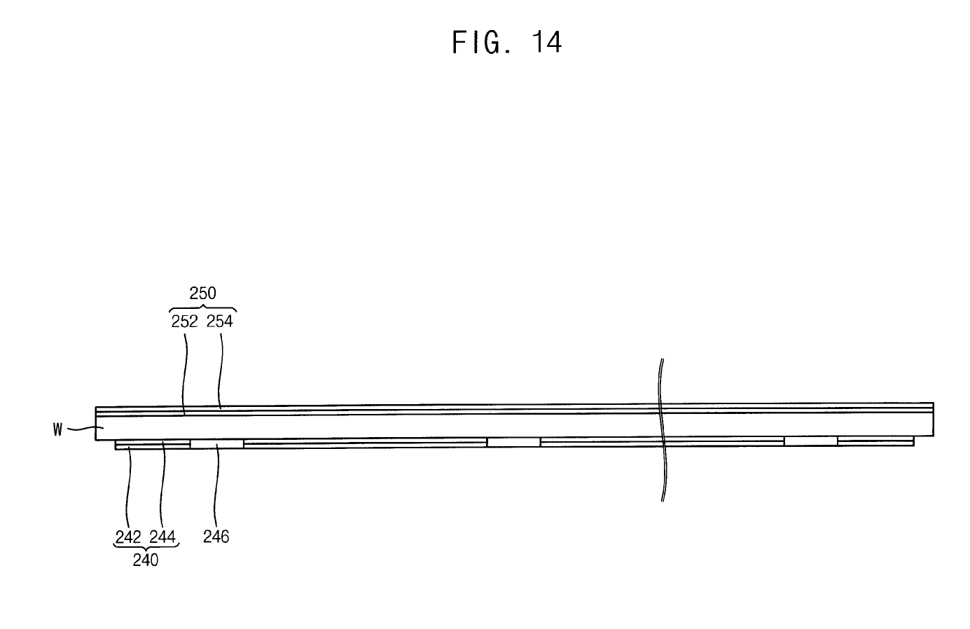

Referring to FIG. 14, the second magnetic shielding film 250 may be attached to an upper surface of the semiconductor substrate W.

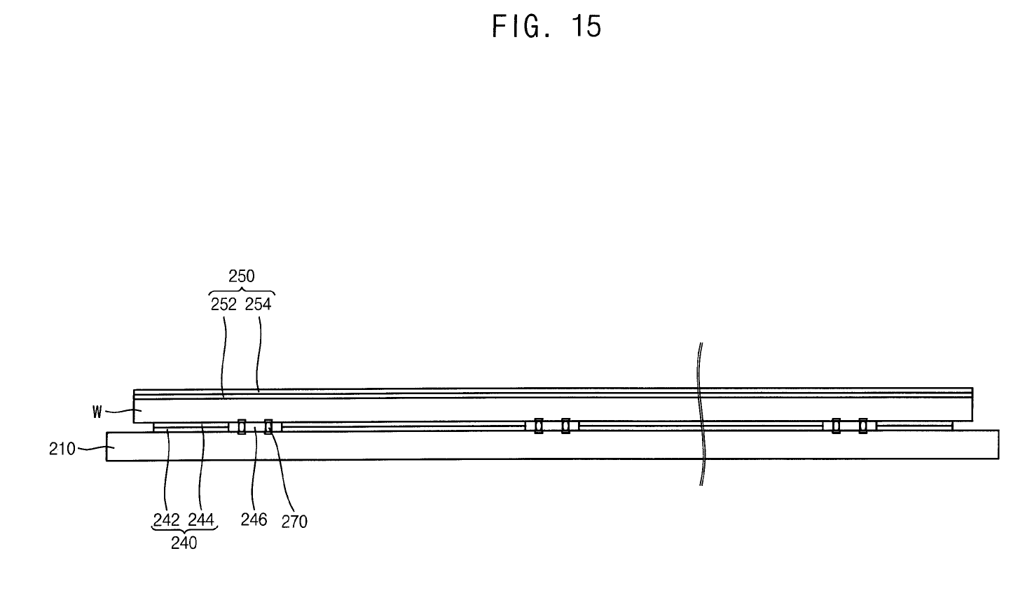

Referring to FIG. 15, the semiconductor substrate W may be attached to the upper surface of the package substrate 210. The bonding pads 222 of the MRAM chip 220 may be electrically connected with the upper pads 212 of the package substrate 210 using the conductive bump 270.

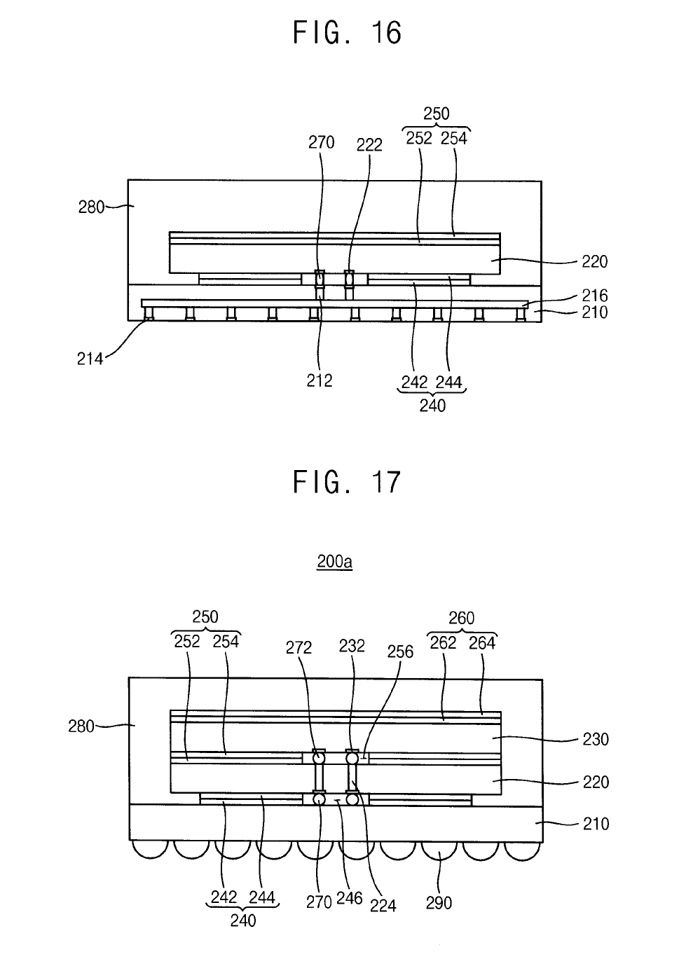

Referring to FIG. 16, the molding member or the molding layer 280 may be formed on the upper surface of the package substrate 210.

The external terminals 290 may be mounted on the lower pads 214 of the package substrate 210. The semiconductor substrate W and the package substrate 210 may be cut along a scribe lane of the semiconductor substrates W to singulate the MRAM chips 220, thereby completing the semiconductor package 200 in FIG. 11.

FIG. 17 is a cross-sectional view illustrating a semiconductor package in accordance with example embodiments.

A semiconductor package 200a of this example embodiment may include elements substantially the same as those of the semiconductor package 200 in FIG. 11 except for further including a second MRAM chip and a third magnetic shielding film. Thus, the same reference numerals may refer to the same elements and any further illustrations with respect to the same elements may be omitted herein for the sake of brevity.

Referring to FIG. 17, a second MRAM chip 230 may be arranged on the second magnetic shielding film 250. The second MRAM chip 230 may include second bonding pads 232. The second bonding pads 232 may be arranged on a substantially central portion of a lower surface of the second MRAM chip 230. The second magnetic shielding film 250 may have openings 256 to expose the second bonding pads 232.

The MRAM chip 220 may include a plug 224. The plug 224 may be vertically arranged in the MRAM chip 220. The plug 224 may have a lower end and an upper end. The lower end of the plug 224 may be electrically connected to the bonding pad 222 of the MRAM chip 220. The upper end of the plug 224 may be exposed through the upper surface of the MRAM chip 220.

A second conductive bump 272 may be arranged in the openings 256. The second conductive bump 272 may be electrically connected to the upper end of the plug 224. Thus, the second bonding pads 232 of the second MRAM chip 230 may be electrically connected with the package substrate 210 through the second conductive bump 272, the first bonding pad 222 and the conductive bump 270.

The third magnetic shielding film 260 may be arranged on an upper surface of the second MRAM chip 230. The third magnetic shielding film 260 may include a third adhesive layer 262 and a third magnetic shielding layer 264 stacked on the third adhesive layer 262. The third adhesive layer 262 may function as to attach the third magnetic shielding layer 264 to the second MRAM chip 230. The third magnetic shielding layer 264 may suppress or reduce magnetic interference between the second MRAM chip 230 and a structure over the second MRAM chip 230. The third magnetic shielding layer 264 may include a metal such as aluminum, copper, nickel, etc.

In example embodiments, the third magnetic shielding film 260 may have the double-layer structure. Alternatively, the third magnetic shielding film 260 may have the triple-layer structure shown in FIG. 10.

A method of manufacturing the semiconductor package 200a in FIG. 17 may include process substantially the same as those illustrated with reference to FIGS. 12 to 16 except for further including a process for forming the second MRAM chip 230 and a process for forming the third magnetic shielding film 260. Thus, any further illustrations with respect to the method of manufacturing the semiconductor package 200a may be omitted herein for the sake of brevity.

According to example embodiments, the MRAM chip may be shielded by the magnetic shielding film having a die attaching function. Thus, the magnetic shielding layer may be arranged between the bonding pads of the MRAM chip. As a result, magnetic interference between the bonding pads may be suppressed. Further, the magnetic shielding film may be attached to the semiconductor substrate including the MRAM chips. Therefore, the semiconductor packaging process may be significantly simplified.

In some embodiments, a semiconductor package comprising: a package substrate; a semiconductor chip having a magnetic memory element arranged over the package substrate and electrically connected with the package substrate; and a first magnetic shielding film attaching the semiconductor chip to the package substrate. The first magnetic shielding film is configured to suppress magnetic interference between the semiconductor chip and the package substrate.

Although the present disclosure has been described with reference to a magnetic random access memory (MRAM) chip, the inventive concepts of the present disclosure can be applied to any semiconductor chip or device that incorporates a magnetic memory element therein within the spirit and scope of the present disclosure. For example, a magnetic memory element having in-plane and/or perpendicular reference layer(s), with a magnetized free layer and a tunnel barrier layer can be included in a semiconductor chip. Thus, the present disclosure can be applied to a system-on-chip (SOC) or a spin transfer torque random access memory (STT-RAM). STT-RAM utilizes magnetic elements written at least in part by a current driven through the magnetic element.

The semiconductor package may also comprise a second magnetic shielding film arranged over the semiconductor chip to reduce magnetic interference at a region over the semiconductor chip. The first magnetic shield film or second magnetic shield film may comprise a metal.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A semiconductor package comprising:
a package substrate;
a magnetic random access memory (MRAM) chip arranged over the package substrate and electrically connected with the package substrate;
a first magnetic shielding film attaching the MRAM chip to the package substrate, the first magnetic shielding film configured to suppress magnetic interference between the MRAM chip and the package substrate; and
a second magnetic shielding film arranged over the MRAM chip to suppress magnetic interference at a region over the MRAM chip.

2. The semiconductor package of claim 1, wherein the first and second magnetic shielding films comprise:
a first adhesive layer; and
a magnetic shielding layer stacked on the first adhesive layer.

3. The semiconductor package of claim 2, wherein the first and second magnetic shielding films further comprise a second adhesive layer stacked on the magnetic shielding layer.

4. The semiconductor package of claim 1, wherein the MRAM chip comprises bonding pads arranged on an upper surface of the MRAM chip, and wherein the bonding pads of the MRAM chip are electrically connected with the package substrate.

5. The semiconductor package of claim 4, wherein the bonding pads of the MRAM chip are electrically connected with the package substrate through conductive wires.

6. The semiconductor package of claim 4, wherein the bonding pads of the MRAM chip are covered by the second magnetic shielding film.

7. The semiconductor package of claim 1, wherein the MRAM chip comprises bonding pads arranged on a lower surface of the MRAM chip, and wherein the bonding pads of the MRAM chip are electrically connected with the package substrate.

8. The semiconductor package of claim 7, wherein the bonding pads of the MRAM chip are electrically connected with the package substrate through conductive bumps.

9. The semiconductor package of claim 7, wherein the first magnetic shielding film has openings configured to expose the bonding pads of the MRAM chip.

10. The semiconductor package of claim 1, further comprising:
a second MRAM chip arranged over the second magnetic shielding film and electrically connected with the package substrate; and
a third magnetic shielding film arranged over the second MRAM chip and configured to cover bonding pads of the second MRAM chip.

11. The semiconductor package of claim 1, further comprising a molding member formed on an upper surface of the package substrate to cover the MRAM chip and the second magnetic shielding film.

12. The semiconductor package of claim 1, further comprising external terminals mounted on a lower surface of the package substrate.

13. A method of manufacturing a semiconductor package, the method comprising:
attaching a first magnetic shielding film to a first surface of a semiconductor substrate including a plurality of MRAM chips;
attaching the semiconductor substrate to a package substrate using the first magnetic shielding film;
electrically connecting the MRAM chips with the package substrate; and
attaching a second magnetic shielding film to a second surface of the semiconductor substrate opposite to the first surface.

14. The method of claim 13, wherein electrically connecting the MRAM chips with the package substrate comprises bonding pads of the MRAM chips with the package substrate.

15. The method of claim 13, wherein electrically connecting the MRAM chips with the package substrate comprises bonding pads of the MRAM chips with the package substrate.

16. The method of claim 15, wherein electrically connecting the MRAM chips with the package substrate further comprises forming openings through the first magnetic shielding film to expose the bonding pads of the MRAM chips.

17. The method of claim 13, further comprising:
attaching a second MRAM chip to an upper surface of the second magnetic shielding film; and
attaching a third magnetic shielding film to an upper surface of the second MRAM chip.

18. A semiconductor package comprising:
a package substrate;
a semiconductor chip having a magnetic memory element arranged over the package substrate and electrically connected with the package substrate; and
a first magnetic shielding film attaching the semiconductor chip to the package substrate, the first magnetic shielding film configured to suppress magnetic interference between the semiconductor chip and the package substrate.

19. The package of claim 18, further comprising a second magnetic shielding film arranged over the semiconductor chip to reduce magnetic interference at a region over the semiconductor chip.

20. The package of claim 18, wherein the first magnetic shield film comprises a metal.
